(19) United States
(12) Patent Application Publication
(10) Pub. No.: US 2008/0014753 A1
(43) Pub. Date: Jan. 17, 2008

(54) Method of Manufacturing a Semiconductor Device Using a Radical Oxidation Process

(76) Inventors: Won-Jun Jang, Seoul (KR); Yong-Woo Hyung, Yongin-si (KR); Jae-Jong Han, Seoul (KR); Ho-Min Son, Suwon-si (KR); Woong Lee, Seoul (KR); Jung-Geun Jee, Seongnam-si (KR)

Correspondence Address: F. CHAU & ASSOCIATES, LLC, 130 WOODBURY ROAD, WOODBURY, NY, 11797, US

(21) Appl. No.: 11/743,774

(22) Filed: May 3, 2007

(30) Foreign Application Priority Data
Jul. 14, 2006 (KR) 2006-66204

(51) Int. Cl. H01L 21/311

(52) U.S. Cl. 438/703; 257/E21.249

(57) ABSTRACT

In a method of manufacturing a semiconductor device, a polysilicon layer doped with impurities is formed on a front side and a backside of a substrate. An insulation layer is formed on the substrate having the polysilicon layer to cover the polysilicon layer on the backside of the substrate. The insulation layer on the front side of the substrate is partially etched to partially expose the front side of the substrate. An oxidation process using oxygen radicals is then carried out to form an oxide layer on the exposed front side of the substrate Thus, when the oxidation process is carried out, the insulation layer prevents impurities in the polysilicon layer on the backside of the substrate from being outgassed. As a result electrical characteristics of the transistor formed on the front side of the substrate may not be deteriorated.

### CROSS-REFERENCE TO RELATED APPLICATION

This application claims priority under 35 USC §119 to Korean Patent Application No. 2006-66204 filed on Jul. 14, 2006, the disclosure of which is hereby incorporated by reference herein in its entirety.

### BACKGROUND OF THE INVENTION

1. Technical Field

The present disclosure relates to a method of manufacturing a semiconductor device and in particular to a method of manufacturing a semiconductor device using a radical oxidation process.

2. Description of the Related Art

Semiconductor memory devices are typically classified as, for example, either a volatile memory device such as a dynamic random access memory (DRAM) and a static random access memory (SRAM) that loses data with the passage of time, and a non-volatile memory device such as a read only memory (ROM) and a flash memory that continuously possesses data regardless of the passage of time and which has a slower data input/output speed.

The non-volatile memory device may have a large storage capacity. Particularly, the flash memory such as an electrically erasable programmable read only memory (EEPROM) device or a flash memory device electrically inputting/outputting data have been widely used A cell of the flash memory device includes a gate electrode having a vertically stacked structure with a silicon substrate and a floating gate formed on the silicon substrate.

The flash memory device includes a memory cell region for storing data using Fowler-Nordheim (F-N) tunneling or hot electrons, and a peripheral circuit region for driving memory cells in the memory cell region.

The peripheral circuit region is divided into a low voltage region in which a low voltage transistor is formed, and a high-voltage region in which a high-voltage transistor enduring a high-voltage of about 20V that is required for the tunneling is formed.

To provide the high-voltage transistor having a high-voltage tolerance, the high-voltage transistor includes a gate oxide layer having a thickness greater than that of the low voltage transistor.

Generally, the gate oxide layer may be formed, for example, by a dry oxidation process using an oxygen gas, a clean oxidation process using an oxygen (O₂) gas and a hydrochloride (HCl) gas, a thermal oxidation process such as a wet oxidation process using water vapor (H₂O), etc.

When the oxide layer is formed by the dry oxidation process or the clean oxidation process, defects such as micro-pores or voids may be generated in the oxide layer. In contrast, defects such as the micro-pores or the voids may not be generated in the oxide layer formed by the wet oxidation process. Further, the oxide layer formed by the wet oxidation process may have an improved time dependent dielectric breakdown (TDDB) characteristic as a long-term reliability index. However, as the oxide layer may grow rapidly in the wet oxidation process, the oxide layer may not be used as a gate oxide layer for a highly integrated semiconductor device.

Therefore, to improve reliability characteristics such as the TDDB, a high-voltage gate oxide layer of a flash memory device, which has a design rule of no more than about 60 nm, has been formed by a radical oxidation process.

According to the radical oxidation process, a source gas such as a hydrogen gas and an oxygen gas is activated to form oxygen radicals. A silicon oxide layer is formed on a silicon substrate by an oxidation reaction between the oxygen radicals and silicon in the silicon substrate. The radical oxidation process may reduce dangling bonds and defects generated in the silicon oxide layer that are formed using the activated oxygen radicals, and thus the silicon oxide layer may be of high quality. Further, although an oxidation reaction speed at an early stage of the radical oxidation process may be rapid, the oxidation reaction speed at the rest of the stages of the radical oxidation process become slower because a portion of the oxide layer formed at the early stage suppresses penetration of the oxygen radicals. Thus, the thickness of the oxide layer may be readily controllable.

The radical oxidation process may be carried out, for example, using a batch type oxidation apparatus as shown in FIG. 1 or a single type oxidation apparatus.

Referring to FIG. 1, the batch type oxidation apparatus simultaneously treats a plurality of semiconductor substrates. The batch type oxidation apparatus includes a boat 22 for loading/unloading the semiconductor substrates 10 into/from a reaction chamber 20, a gas inlet 28 for supplying a reaction gas and other gases into the reaction chamber 20, a vacuum port 30 for maintaining a pressure in the reaction chamber 20, and a heater 26 for maintaining a desired temperature for the reaction chamber 20. Further, the boat 22 has a plurality of slots 24a, 24b and 24c into which the semiconductor substrates 10 are inserted.

The single type oxidation apparatus treats semiconductor substrates one by one. The single type oxidation apparatus includes a plate for supporting the single semiconductor substrate.

Here, when the radical oxidation process is carried out using the single type oxidation apparatus, the semiconductor substrate may become locally warped so that the locally warped semiconductor substrate may be misaligned in a following photolithography process. Thus, the batch type oxidation apparatus is currently used for the radical oxidation process.

Hereinafter, a conventional method of manufacturing a flash memory device that includes a high-voltage gate oxide layer of a high-voltage transistor using the batch type oxidation apparatus is illustrated with reference to FIGS. 1 and 2.

Referring to FIG. 1, a tunnel oxide layer, e.g., a gate oxide layer of a memory cell transistor, a floating polysilicon layer, a dielectric layer such as an oxide/nitride/oxide (ONO) layer, and a control polysilicon layer 12 are sequentially formed on a semiconductor substrate 10, that is, a silicon wafer having a memory cell region and a peripheral circuit region.

The layers on the peripheral circuit region of the semiconductor substrate 10 are removed by a photolithography process. A radical oxidation process is performed on the peripheral circuit region of the semiconductor substrate 10 using the batch type oxidation apparatus in FIG, 1 to form a high-voltage gate oxide layer 14 on the peripheral circuit region of the semiconductor substrate 10.

A mask pattern is formed on a first region where a high-voltage transistor is formed to expose a second region where a low-voltage transistor is formed. The high-voltage gate oxide layer 14 in the second region is etched using the mask pattern as an etching mask. A thin low-voltage gate oxide layer is formed on the second region.

A high-voltage gate electrode and a low-voltage gate electrode are formed on the peripheral circuit region of the semiconductor substrate 10 by a deposition process and a photolithography process to form a peripheral circuit transistor including the high-voltage transistor and the low-voltage transistor The layers on the memory cell regions are patterned to form a vertically stacked gate electrode of a memory cell transistor including a floating gate and a control gate.

According to the conventional method, the high-voltage gate oxide layer 14 formed by the radical oxidation process may have improved reliability. However, the peripheral circuit transistor may have inadequate electrical distribution characteristics.

Particularly, when the radical oxidation process is performed using the batch type oxidation apparatus in FIG. 1, the high-voltage gate oxide layers 14 in each of the slots 24a, 24b and 24c may have thicknesses different from one another Particularity a thickness difference between an uppermost high-voltage gate oxide layer in the first slot 24a and other high-voltage gate oxide layers in other slots 24b and 24c may be more significant. These thickness differences may be caused because the thickness and the quality of an oxide layer formed on an adjacent semiconductor substrate may be influenced by a backside of a semiconductor substrate. The thickness difference may be generated between a central portion and an edge portion of a single semiconductor substrate as well as between the vertically arranged semiconductor substrates. The thickness difference of the high-voltage gate oxide layers 14 in each of the slots 24a, 24b and 24c may change a threshold voltage of the peripheral circuit transistor so that the peripheral circuit transistor may have inadequate electrical distribution characteristics.

Further, in an oxidation process and a deposition process using a furnace, a layer is formed on a backside of a semiconductor substrate as well as a front side of the semiconductor substrate. For example, as shown if FIG, 2, a control polysilicon layer 12 doped with impurities such as phosphine (PH₃) is formed on a backside b of a semiconductor substrate 10 as well as a front side f of the semiconductor substrate 10. Therefore, after removing the control polysilicon layer 12 in the peripheral circuit region, the control polysilicon layer 12 remains on the backside b of the semiconductor substrate 10.

When the radical oxidation process is carried out on the semiconductor substrate 10 under conditions that the control polysilicon layer 12 remains on the backside b of the semiconductor substrate 10 using the batch type oxidation apparatus 10, the impurities in the control polysilicon layer 12 on the backside b of the semiconductor substrate 10 are outgassed, because the radical oxidation process is performed under a low pressure of no more than about several mTorr. The peripheral circuit region of the semiconductor substrate 10 adjacently positioned under the control polysilicon layer 12 is doped with the outgassed impurities. As a result, an impurity concentration of the peripheral circuit region may be altered so that electrical characteristics of the transistor formed on the peripheral circuit region may be deteriorated.

### SUMMARY OF THE INVENTION

Exemplary embodiments of the present invention provide a method of manufacturing a semiconductor device that prevents impurities in a backside of a substrate from being outgassed during forming an oxide layer on the substrate using a batch type radical oxidation process.

In accordance with an exemplary embodiment of the present invention, a method of manufacturing a semiconductor device is provided. The method includes forming a polysilicon layer doped with impurities on a front side and a backside of a substrate, forming an insulation layer on the substrate having the polysilicon layer to cover the polysilicon layer on the backside of the substrate with the insulation layer. The method further includes performing an etching process to partially expose the front side of the substrate and performing an oxidation process using oxygen radicals to form an oxide layer on the exposed front side of the substrate.

According to an exemplary embodiment, the oxidation process may be carried out using a batch type oxidation process Further, the insulation layer may include a nitride layer, an oxide layer, an oxynitride layer, etc.

According to another exemplary embodiment, the polysilicon layer may have an opening for partially exposing the front side of the substrate. Further, the insulation layer may be formed on the polysilicon layer and the exposed front side of the substrate.

According to still another exemplary embodiment, the oxidation process may be carried out on the insulation layer formed on the entire front side of the substrate to partially expose the front side of the substrate through the opening.

Alternatively, the oxidation process may be carried out on the insulation layer partially formed on the front side of the substrate to partially expose the front side of the substrate through the opening.

According to yet still another exemplary embodiment, the polysilicon layer may be formed on the entire front side of the substrate. Further, the insulation layer may be formed on an entire face of the polysilicon layer.

According to yet still another exemplary embodiment, the etching process may be carried out on the insulation layer and the polysilicon layer to partially expose the front side of the substrate.

According to yet still another exemplary embodiment, after forming the oxide layer, the insulation layer and the polysilicon layer remaining on the front side of the substrate are patterned to form a conductive structure.

According to yet still another exemplary embodiment, the insulation layer may be formed by oxidizing a surface of the polysilicon layer.

In accordance with an exemplary embodiment of the present invention, a method of manufacturing a non-volatile memory device is provided. The method includes preparing a substrate having a memory cell region and a peripheral circuit region, and forming a gate structure on at least substantially an entire surface of the substrate. The gate structure includes a tunnel oxide layer, a floating polysilicon layer, a dielectric layer and a control polysilicon layer. The method further includes forming a hard mask layer on at least substantially an entire surface of the gate structure, removing the hard mask layer and the gate structure on the peripheral circuit region to expose a surface of the peripheral circuit region and performing an oxidation process using oxygen radicals to form a gate oxide layer on the exposed surface of the peripheral circuit region.

According to an exemplary embodiment, the oxidation process may be carried out using a batch type oxidation process. Further, the hard mask layer may include a nitride layer, an oxide layer, an oxynitride layer, etc.

According to another exemplary embodiment, a transistor structure including the gate oxide layer may be further formed on the peripheral circuit region. Furthermore, after forming the gate oxide layer, the gate structure may be patterned to form a memory cell structure on the memory cell region.

According to exemplary embodiments of the present invention, when the oxide layer is formed on the substrate, the insulation layer prevents impurities in the polysilicon layer on the backside of the substrate from being outgassed. Thus, the front side of the substrate may not be influenced by the impurities. As a result, electrical characteristics of the transistor formed on the front side of the substrate may not be deteriorated.

### BRIEF DESCRIPTION OF THE DRAWINGS

Exemplary embodiments of the invention can be understood in more detail from the following detailed description taken in conjunction with the accompanying drawings wherein:

FIG. 1 is a cross-sectional view illustrating a conventional batch type oxidation apparatus;

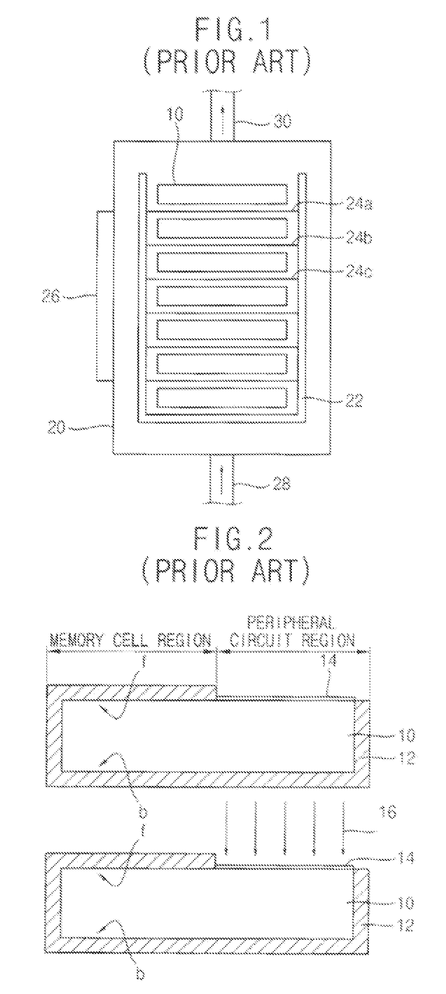

FIG. 2 is a cross-sectional view illustrating a conventional method of manufacturing a semiconductor device using a batch type oxidation process;

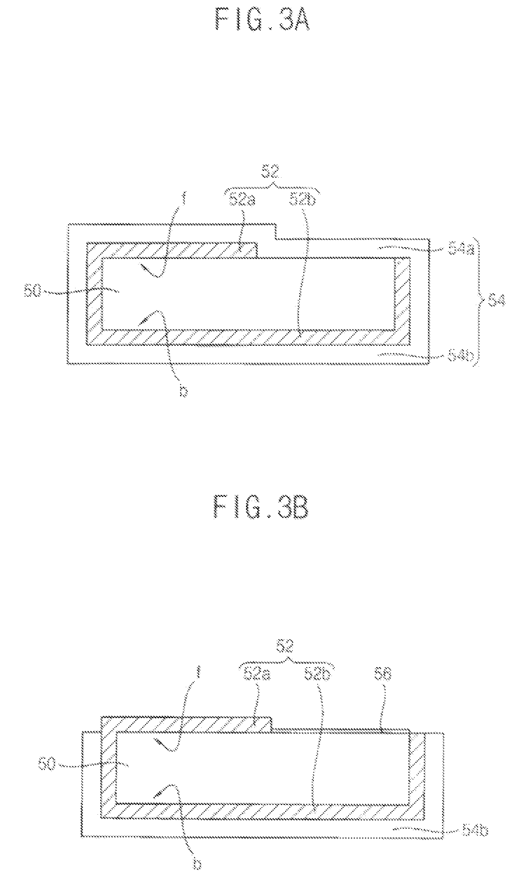

FIGS. 3A and 3B are cross-sectional views illustrating a method of manufacturing a semiconductor device using a radical oxidation process in accordance with an exemplary embodiment of the present invention;

FIG, 4 is a cross-sectional view illustrating a batch type oxidation apparatus for forming a semiconductor device using the method in FIGS. 3A and 3B; and

FIGS. 5A and 5B are cross-sectional views illustrating a method of manufacturing a semiconductor device using a radical oxidation process in accordance with an exemplary embodiment of the present invention,

### DETAILED DESCRIPTION OF THE EXEMPLARY EMBODIMENTS OF THE INVENTION

The present invention is described more fully hereinafter with reference to the accompanying drawings, in which exemplary embodiments of the invention are shown. This invention may, however, be embodied in many different forms and should not be construed as limited to the embodiments set forth herein. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context dearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

### Exemplary Embodiment 1

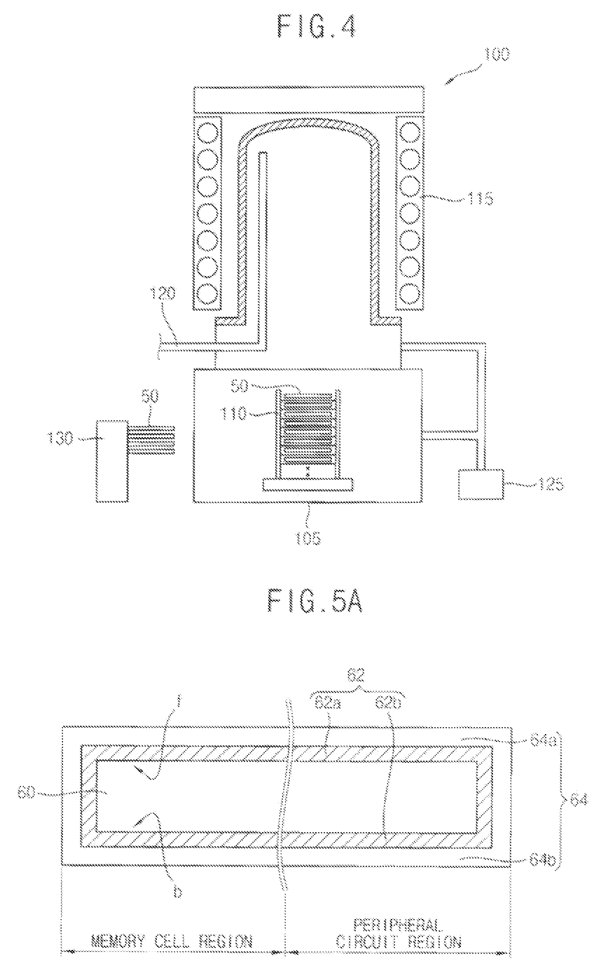

FIGS. 3A and 3B are cross-sectional views illustrating a method of manufacturing a semiconductor device using a radical oxidation process in accordance with a first exemplary embodiment of the present invention, and FIG. 4 is a cross-sectional view illustrating a batch type oxidation apparatus for forming a semiconductor device using the method in FIGS. 3A and 3B.

Referring to FIG. 3A, a polysilicon layer 52 doped with impurities is formed on a semiconductor substrate 50 such as, for example, a single crystalline silicon wafer. Here, the polysilicon layer 52 may be formed on an entire surface of the semiconductor substrate 50. For example, the polysilicon layer 52 includes an upper polysilicon layer 52a formed on a front side f of the semiconductor substrate 50 and a lower polysilicon layer 52b formed on a backside b of the semiconductor substrate 50.

The polysilicon layer 52 may be formed, for example by a low-pressure chemical vapor deposition (LPCVD) process. Generally, as a layer is formed on the backside b of the semiconductor substrate 50 as well as the front side f of the semiconductor substrate 50 by an oxidation process and a deposition process using a furnace, the polysilicon layer 52 is formed on the front side f and the backside b of the semiconductor substrate 50.

The upper polysilicon layer 52a of the polysilicon layer 52 on the front side f of the semiconductor substrate 50 is etched to form an opening for partially exposing the front side f of the semiconductor substrate 50. For example, a photoresist pattern is formed on the upper polysilicon layer 52a by a photolithography process. The upper polysilicon layer 52a is etched using the photoresist pattern as an etching mask to expose the front side f of the semiconductor substrate 50 through the opening. Here, an oxide layer may be formed on the exposed front side f of the semiconductor substrate 50 by a following process. Further, the lower polysilicon layer 52b still remains after completing the etching process.

An insulation layer 54 is formed on the polysilicon layer 52 having the opening and the exposed front side f of the semiconductor substrate 50. Here the insulation layer 54 includes an upper insulation layer 54a formed over the front side f of the semiconductor substrate 50, and a lower insulation layer 54b formed under the backside b of the semiconductor substrate 50.

The insulation layer 54 may include, for example, a nitride layer, an oxide layer, an oxynitride layer, etc. Further, the insulation layer 54 may be formed, for example, by a chemical vapor deposition (CVD) process, an LPCVD process, a plasma-enhanced CVD (PECVD) process, etc. Furthermore, to prevent electrical characteristics of a transistor which is to be formed on the front side f of the semiconductor substrate, from being deteriorated, the insulation layer 54 may be formed at a temperature of no more than about 800° C.

For example, the insulation layer 54 includes a silicon nitride layer. Further, the silicon nitride layer may be formed by an LPCVD process at a temperature of about 600° C. to about 700° C.

Referring to FIGS. 3B and 4, the entire upper insulation layer 54a on the front side f of the semiconductor substrate 50 is removed. Thus, the lower insulation layer 54b on the backside b of the semiconductor substrate 50 remains. For example, an etch-back process is carried out on the upper insulation layer 54b on the front side f of the semiconductor substrate 50 to remove the entire upper insulation layer 54b. Further, after completing the etch-back process, the front side f of the semiconductor substrate 50 is partially exposed through the opening of the upper polysilicon layer 52a.

Alternatively, the upper insulation layer 54a on the front side f of the semiconductor substrate 50 may be partially removed to partially expose the front side f of the semiconductor substrate 50 through the opening.

The semiconductor substrate 50 is loaded into a reaction chamber 100 of a batch type oxidation apparatus shown in FIG. 4.

For example, a transfer unit 130 such as a handier transfers the semiconductor substrate 50 to a boat 110 in a loadlock chamber 105. Here, the boat 110 has a plurality of slots into which a plurality of the semiconductor substrates 50 is inserted.

A pressure control unit 125 such as a vacuum pump provides the loadlock chamber 105 and the reaction chamber 100 with vacuum. The boat 105 having the semiconductor substrates 50 is loaded into the reaction chamber 100 having a temperature of about 600° C.

The pressure control unit 125 provides the reaction chamber 100 with a low pressure of about 0.4 mTorr to about 2 mTorr. An energy supply unit 115 such as a heater heats the reaction chamber 100 to a temperature of about 850° C. to about 900° C. A reaction gas including oxygen radicals is introduced into the reaction chamber 100 through a gas line 120.

For example, a mixed gas having an oxygen gas and a hydrogen gas is introduced into the reaction chamber 100 through the gas line 120. A microwave is applied to the mixed gas in the gas line 120 to form the reaction gas in plasma state including the oxygen radicals.

The oxygen radicals in the reaction chamber 100 are reacted with the exposed front side f of the semiconductor substrate 50 to form an oxide layer on the exposed front side f of the semiconductor substrate 50.

Here, to generate sufficient oxygen radicals, the radical oxidation process may be performed under a tow pressure of about several mTorr Thus, impurities in the lower polysilicon layer 52b on the backside b of the semiconductor substrate 50 are outgassed. A front side f of a semiconductor substrate adjacently under the semiconductor substrate 50 is doped with the outgassed impurities However, according to this exemplary embodiment, the lower insulation layer 54b covers the tower polysilicon layer 52b on the backside b of the semiconductor substrate 50 so that the impurities may not be outgassed from the tower polysilicon layer 52b during the radical oxidation process.

### Exemplary Embodiment 2

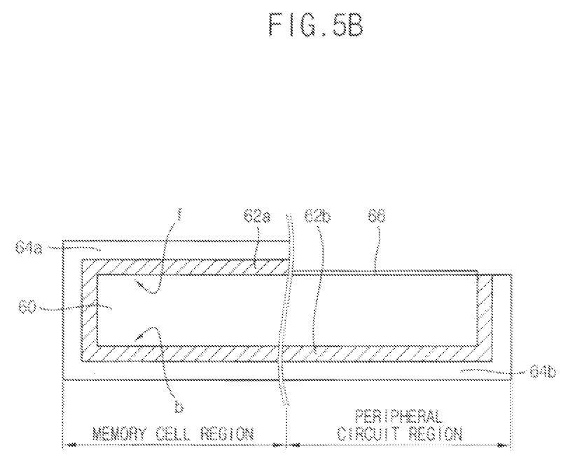

FIGS. 5A and 5B are cross-sectional views illustrating a method of manufacturing a semiconductor device using a radical oxidation process in accordance with a second exemplary embodiment of the present invention. For example, FIGS. 5A and 5B illustrate a method of forming a high-voltage gate oxide layer of a flash memory device. Further; layers interposed between a semiconductor substrate and a polysilicon layer are not depicted in FIGS. 5A and 5B for convenience.

Referring to FIG. 5A, an isolation process such as, for example, a shallow trench isolation (STI) process is carried out on a semiconductor substrate 60 having a memory cell region and a peripheral circuit region to define an active region and a field region of the semiconductor substrate 60. Alternatively, the field region may be defined by, for example, a local oxidation of silicon (LOCOS) process. Further, a floating gate and the active region may be simultaneously formed by, for example, a self-aligned STI (SA-STI) process.

A gate structure including a tunnel oxide layer, a floating polysilicon layer, a dielectric layer, a control polysilicon layer 62 and a hard mask layer 64 sequentially stacked is formed on the semiconductor substrate 60.

Here, the control polysilicon layer 62 includes an upper control polysilicon layer 62a formed on a front side f of the semiconductor substrate 60, and a lower control polysilicon layer 62b formed on a backside b of the semiconductor substrate 60. Further, the hard mask layer 64 includes an upper mask layer 64a formed over the front side f of the semiconductor substrate 60, and a lower mask layer 64b formed under the backside b of the semiconductor substrate 60.

For example, an oxidation process is performed to form the tunnel oxide layer, that is, a gate oxide layer of a memory cell transistor on the active region of the semiconductor substrate 60.

The floating polysilicon layer is formed on the semiconductor substrate 60 having the tunnel oxide layer by, for example, an LPCVD process. The floating polysilicon layer is doped with impurities by a doping process such as, for example, a phosphorus chloride oxide (POCl₃) diffusion process, an ion implantation process, an in-situ doping process, etc., to form a heavily doped N-type floating polysilicon layer. The floating polysilicon layer on the field region is removed by, for example, a photolithography process to form a floating gate pattern.

The dielectric layer such as, for example, an oxide/nitride/oxide (ONO) layer is formed on the floating polysilicon layer and the semiconductor substrate 60 by an oxidation process and a CVD process.

The control polysilicon layer 62 is formed on the dielectric layer by, for example, an LPCVD process. The control polysilicon layer 62 is doped with impurities by a doping process such as, for example, a phosphorus chloride oxide (POCl₃) diffusion process, an ion implantation process, an in-situ doping process, etc., to form a heavily doped N-type control polysilicon layer.

The hard mask layer 64 for patterning a gate is formed on the control polysilicon layer 62. For example, the hard mask layer 64 includes a nitride layer, an oxide layer, a combination thereof, etc. Further, the hard mask layer 64 may be formed by, for example, a CVD process, an LPCVD process, a PE-CVD process, etc.

In this exemplary embodiment, the hard mask layer 64 includes a silicon nitride layer. The silicon nitride layer may be formed by, for example, an LPCVD process at a temperature of about 600° C. to about 700° C.

Here, as the control polysilicon layer 62 and the hard mask layer 64 are formed by an LPCVD process using a furnace, the control polysilicon layer 62 and the hard mask layer 64 are formed on the backside b of the semiconductor substrate 60 as well as the front side f of the semiconductor substrate 60. Further, the tunnel oxide layer, the floating polysilicon layer and the dielectric layer are formed on the front side f and the backside b of the semiconductor substrate 60.

Referring to FIG. 5B, the gate structure on the front side f of the peripheral circuit region of the semiconductor substrate 60 is selectively removed. Here, the gate structure including the lower control polysilicon layer 62b and the lower mask layer 64b on the backside b of the semiconductor substrate 60 still remains after removing the gate structure.

The semiconductor substrate 60 is loaded into the reaction chamber 100 of a batch type oxidation apparatus shown in FIG. 4.

A radical oxidation process is performed on the semiconductor substrate 60 in the batch type oxidation apparatus. Here, to convert a source gas into radicals, the radical oxidation process may be carried out under a pressure lower than that of a thermal oxidation process. For example, the radical oxidation process is carried out using a reaction gas including oxygen radicals under a low pressure of about 0.4 mTorr to about 2 mTorr.

The reaction gas may be obtained by activating a mixed gas including, for example, a hydrogen gas and an oxygen gas. A gate oxide layer 66 of a high-voltage transistor is formed on the peripheral circuit region of the semiconductor substrate 60 by an oxidation reaction between the oxygen radicals and silicon in the semiconductor substrate 60.

Here, the oxidation process using the oxygen radicals may have an improved oxidation reactivity regardless of the kinds of oxidized materials. Thus, the gate oxide layer 66 formed by the radical oxidation process may have reduced dangling bonds and defects so that the gate oxide layer 66 may thereby have improved reliability.

After completing the radical oxidation process, the semiconductor substrate 60 having the gate oxide layer 66 is unloaded from the reaction chamber 100 of the batch type oxidation apparatus. A mask pattern is formed on a first region of the peripheral circuit region where a high-voltage transistor is formed to expose a second region where a low-voltage transistor is formed. The high-voltage gate oxide layer 66 in the second region is etched using the mask pattern as an etching mask. A thin low-voltage gate oxide layer is formed on the second region.

A high-voltage gate electrode and a low-voltage gate electrode are formed on the peripheral circuit region of the semiconductor substrate 60 by, for example, a deposition process and a photolithography process to form a peripheral circuit transistor including the high-voltage transistor and the low-voltage transistor. A memory cell structure is then formed on the memory cell region of the semiconductor substrate 60.

For example, the upper mask layer 64a on the front side f of the semiconductor substrate 60 in the memory cell region is patterned to form a hard mask. The upper control polysilicon layer 62a, the dielectric layer and the floating gate pattern are dry-etched using the hard mask as an etching mask to form the memory cell structure including a floating gate and a control gate on the front side f of the semiconductor substrate 60 in the memory cell region.

Here, while the LPCVD process is carried out to form the high-voltage gate oxide layer 66, the lower mask layer 64b covers the lower control polysilicon layer 62 on the backside b of the semiconductor substrate 60. Therefore, impurities may not be outgassed from the lower control polysilicon layer 64b. As a result, a front side of a semiconductor substrate adjacently under the semiconductor substrate 60 may not be doped with the outgassed impurities so that electrical characteristics of the peripheral transistor may not be deteriorated.

Alternatively, before performing the batch type radical oxidation process, an oxidation process may be additionally carried out to form an insulation layer That is, the lower polysilicon layer on the backside of the semiconductor substrate may be oxidized to prevent the impurities in the lower polysilicon layer from being outgassed.

According to exemplary embodiments of the present invention, while the radical oxidation process is carried out on the semiconductor substrate having the front side and the backside on which the polysilicon layer is doped with impurities, the insulation layer covers the lower polysilicon layer on the backside of the semiconductor substrate.

Therefore, the impurities may not be outgassed from the lower polysilicon layer As a result, the outgassed impurities may have no influence on a front side of a semiconductor substrate adjacently under the semiconductor substrate so that electrical characteristics of the peripheral transistor may not be deteriorated.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of manufacturing a semiconductor device, comprising:
forming a polysilicon layer doped with impurities on a front side and a backside of a substrate;
forming an insulation layer on the substrate having the polysilicon layer to cover the polysilicon layer on the backside of the substrate with the insulation layer;
performing an etching process to partially expose the front side of the substrate; and
performing an oxidation process using oxygen radicals to form an oxide layer on the exposed front side of the substrate.

2. The method of claim 1, wherein the oxidation process is performed using a batch type oxidation apparatus.

3. The method of claim 1, wherein the insulation layer comprises a nitride layer, an oxide layer or an oxynitride layer.

4. The method of claim 1, wherein the polysilicon layer has an opening for exposing the front side of the substrate, and the insulation layer is formed on the polysilicon layer and the front side of the substrate exposed through the opening.

5. The method of claim 4, wherein the etching process is performed on the insulation layer which is formed on the entire front side of the substrate to partially expose the front side of the substrate through the opening.

6. The method of claim 4, wherein the etching process is performed on the insulation layer which is partially formed on the front side of the substrate to partially expose the front side of the substrate through the opening.

7. The method of claim 1, wherein the polysilicon layer is formed on an entire face of the substrate, and the insulation layer is formed on an entire face of the polysilicon layer.

8. The method of claim 7, wherein the etching process is performed on the insulation layer and the polysilicon layer to partially expose the front side of the substrate.

9. The method of claim 1, further comprising patterning the insulation layer and the polysilicon layer on the front side of the substrate to form a conductive structure, after forming the oxide layer.

10. The method of claim 1, wherein the insulation layer is formed by oxidizing a surface of the polysilicon layer.

11. A method of manufacturing a non-volatile memory device, comprising:
preparing a substrate that has a memory cell region and a peripheral circuit region;
forming a gate structure on at least substantially an entire surface of the substrate, the gate structure including a tunnel oxide layer, a floating polysilicon layer, a dielectric layer and a control polysilicon layer;
forming a hard mask layer on at least substantially an entire surface of the gate structure;
removing the hard mask layer and the gate structure on the peripheral circuit region to expose a surface of the peripheral circuit region; and
performing an oxidation process using oxygen radicals to form a gate oxide layer on the exposed surface of the peripheral circuit region.

12. The method of claim 11, wherein the oxidation process is performed using a batch type oxidation apparatus.

13. The method of claim 11, wherein the hard mask layer comprises a nitride layer, an oxide layer or an oxynitride layer.

14. The method of claim 11, further comprising forming a transistor including the gate oxide layer on the peripheral circuit region.

15. The method of claim 11, further comprising patterning the gate structure to form a memory cell structure on the memory cell region, after forming the gate oxide layer,
